(19) United States
(12) Patent Application Publication
(10) Pub. No.: US 2025/0275115 A1
(43) Pub. Date: Aug. 28, 2025

(54) Memory Circuitry And Methods Used In Forming Memory Circuitry

(71) Applicant: Micron Technology, Inc., Boise, ID (US)

(72) Inventors: Brenda Li, Boise, ID (US); David Daycock, Boise, ID (US); Muralikrishnan Balakrishnan, Boise, ID (US); Sok Han Wong, Boise, ID (US); Joo Ming Simon Lim, Meridian, ID (US); Si-Woo Lee, Saratoga, CA (US); Mark Fischer, Meridian, ID (US)

(73) Assignee: Micron Technology, Inc., Boise, ID (US)

(21) Appl. No.: 19/042,199

(22) Filed: Jan. 31, 2025

Related U.S. Application Data
(60) Provisional application No. 63/557,745, filed on Feb. 26, 2024.

(51) Int. Cl. H10B 12/00

(52) U.S. Cl. CPC H10B 12/05; H10B 12/03; H10B 12/30

(57) ABSTRACT

A method used in forming memory circuitry comprising memory cells comprises forming vertically-alternating insulative tiers and memory-cell tiers. The memory cells individually comprise a horizontal transistor comprising a gate and channel material operatively-proximate the gate. The gate comprises part of one of a plurality of horizontal conductive access lines that individually directly electrically couple together multiple of the gates of different ones of the horizontal transistors that are in the same memory-cell tier. The access lines and channel material extend horizontally from the memory-array region into a connection region. Through a contact opening in the connection region, the channel material in the connection region is replaced with conductive material. The conductive material is directly against one of the access lines in the connection region and comprises part of a conductive-via construction in the connection region. Structure independent of method is also disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory array region having horizontal tiers in which individual memory cells are received (e.g., arrayed in x and y directions). The stack in the 3D memory array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-29 are diagrammatic sequential sectional and/or enlarged views of the construction, or portions thereof or alternate and/or additional embodiments, in process in accordance with some embodiments of the invention.

### DETAILED DESCRIPTION OF EXAMPLE EMBODIMENTS

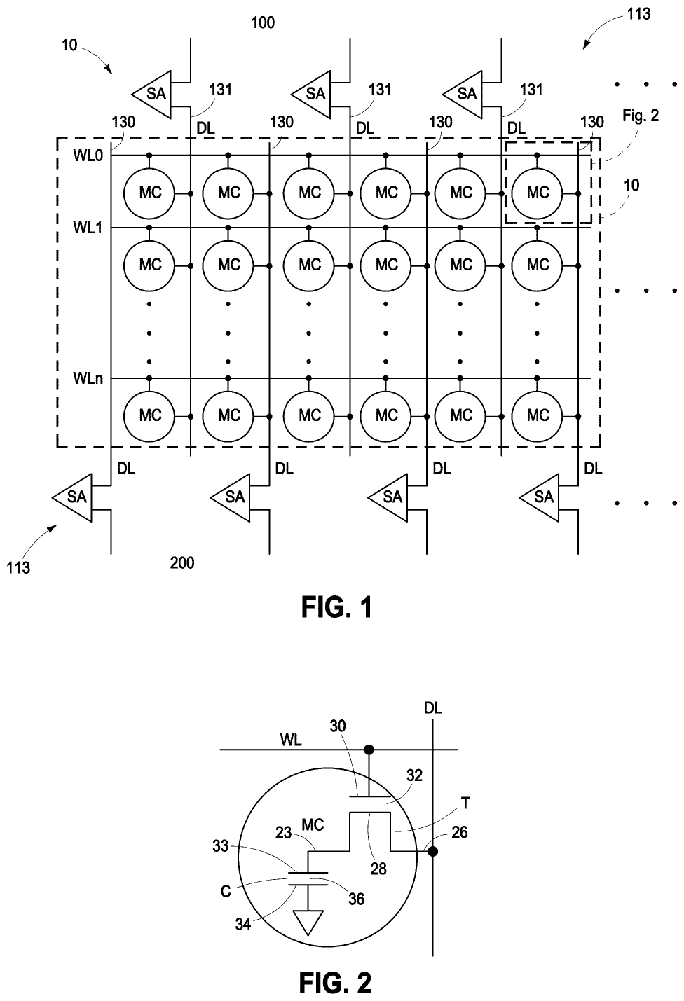

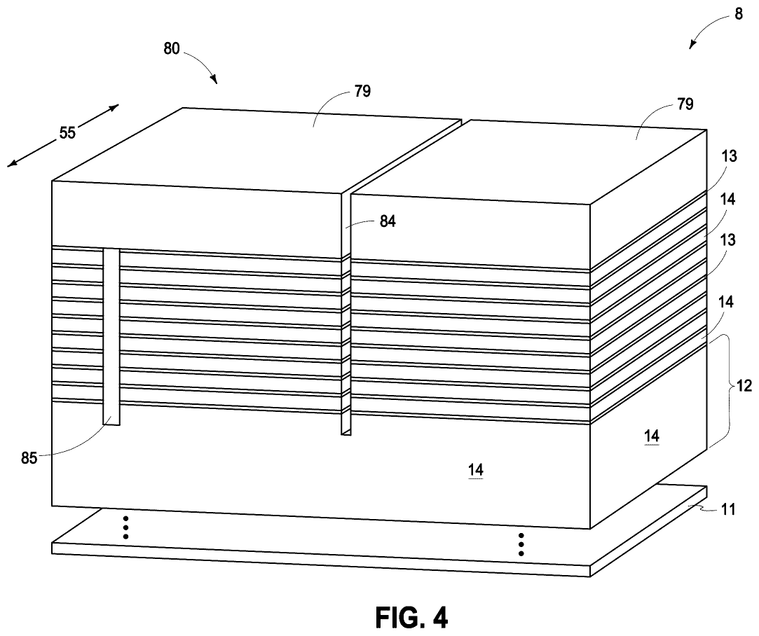

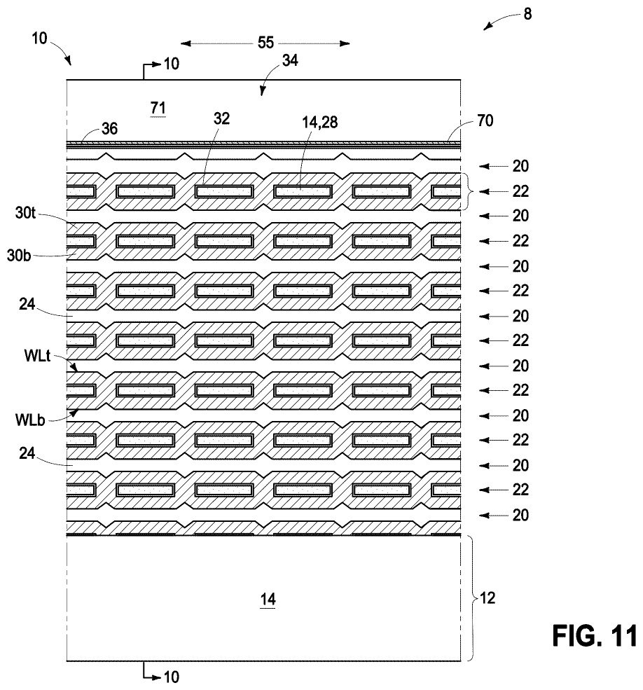

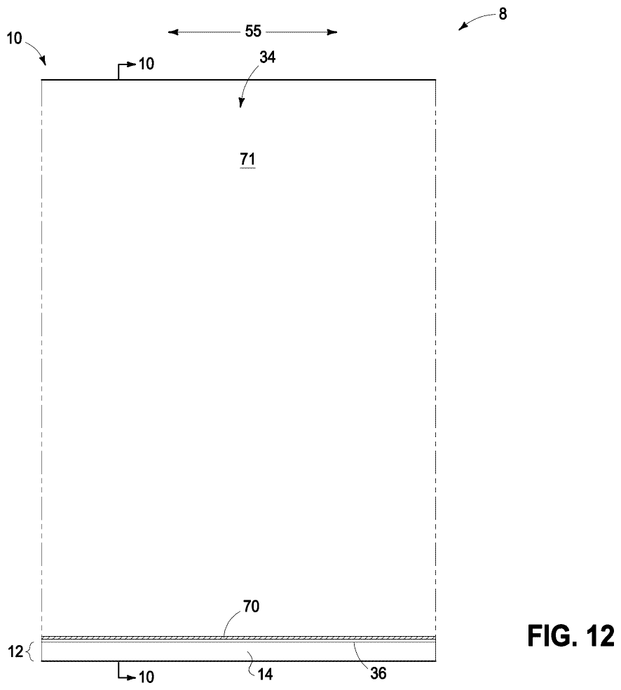

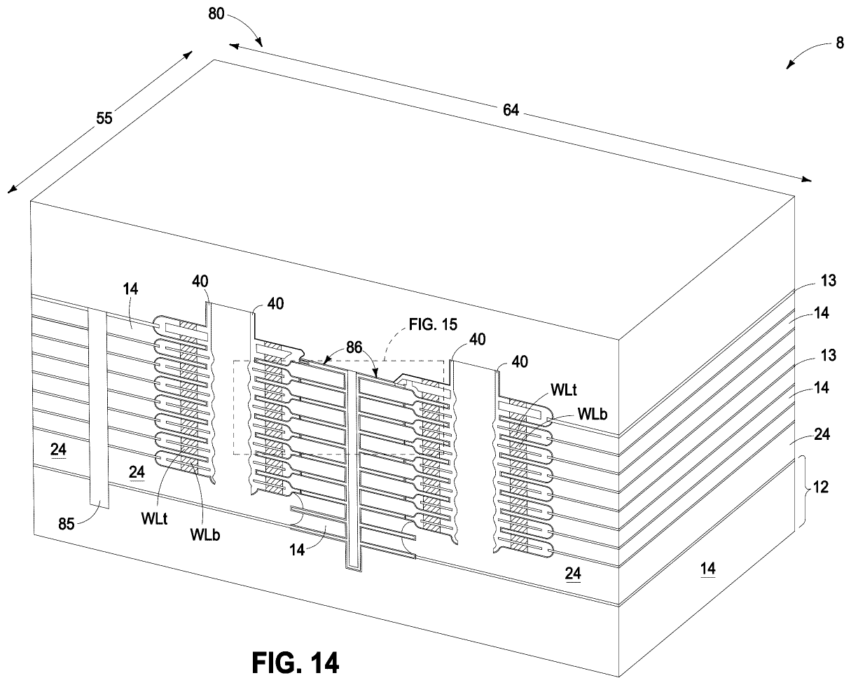

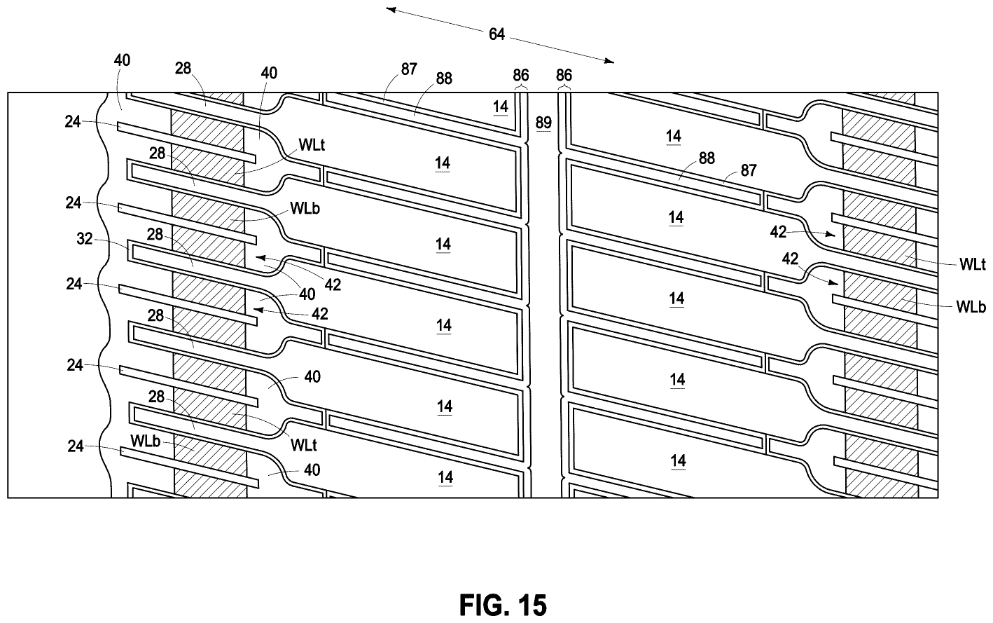

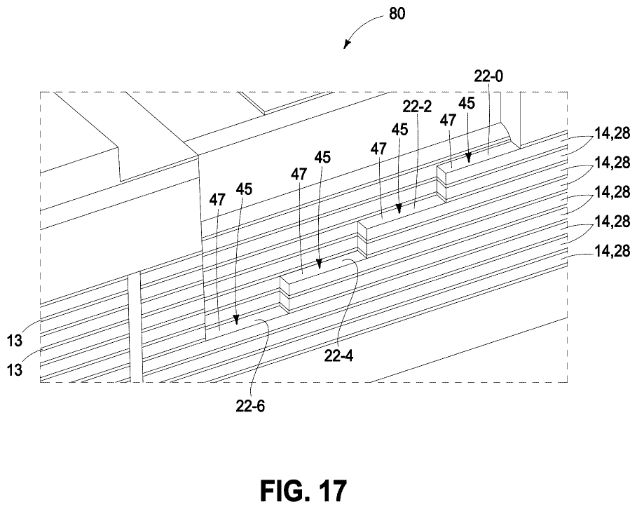

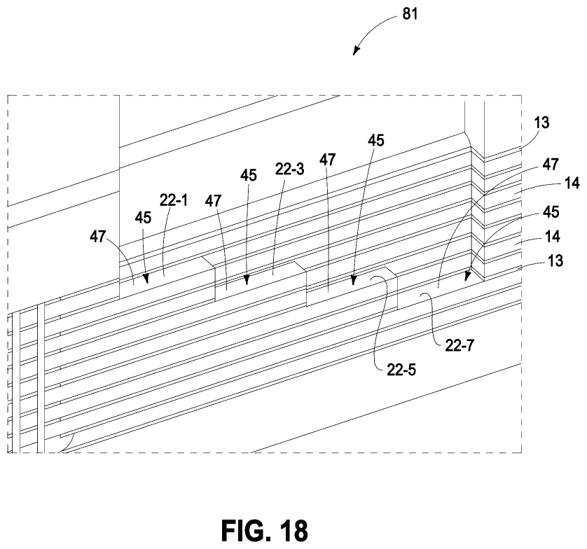

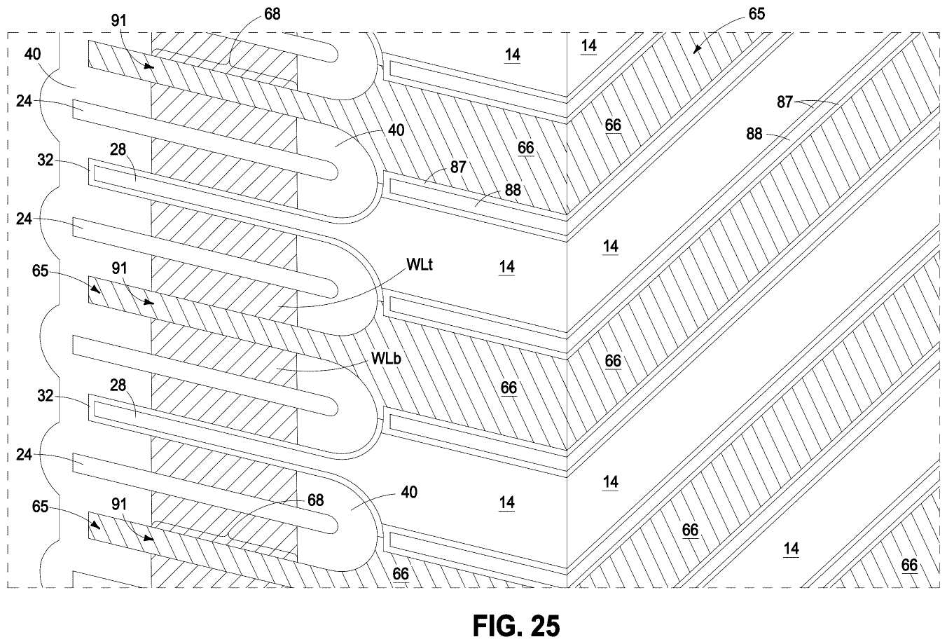

Embodiments of the invention encompass memory circuitry (e.g., DRAM) having vertically-alternating tiers of insulative material and memory cells, with the memory cells individually comprising a capacitor and a horizontally-oriented transistor. Embodiments of the invention also encompass methods used in forming such memory circuitry. Example method embodiments are first described with reference to FIGS. 1-29.

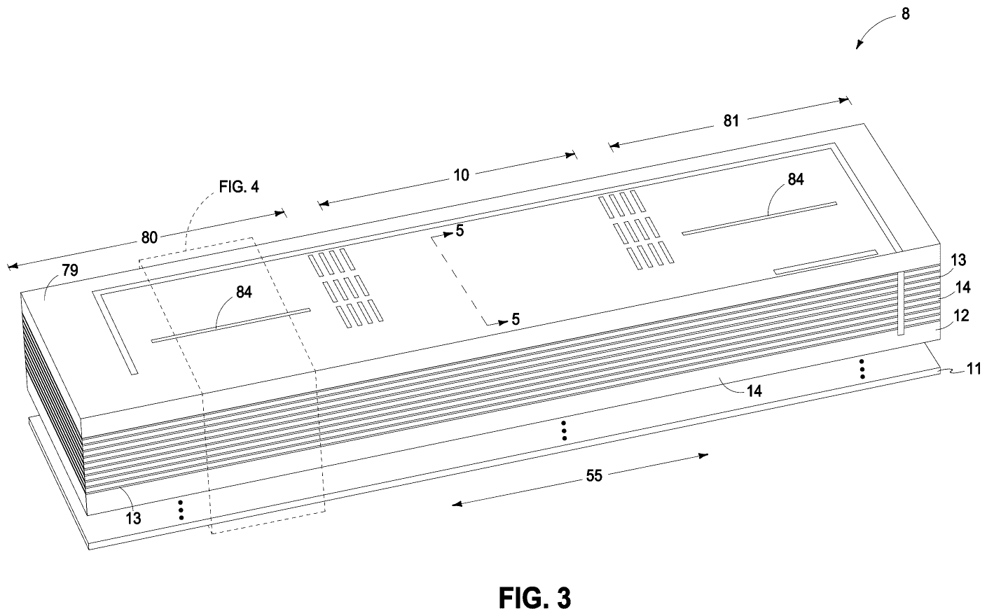

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part of) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIGS. 3+ have the wordlines/access lines running horizontally and the digitlines/sense lines running vertically.

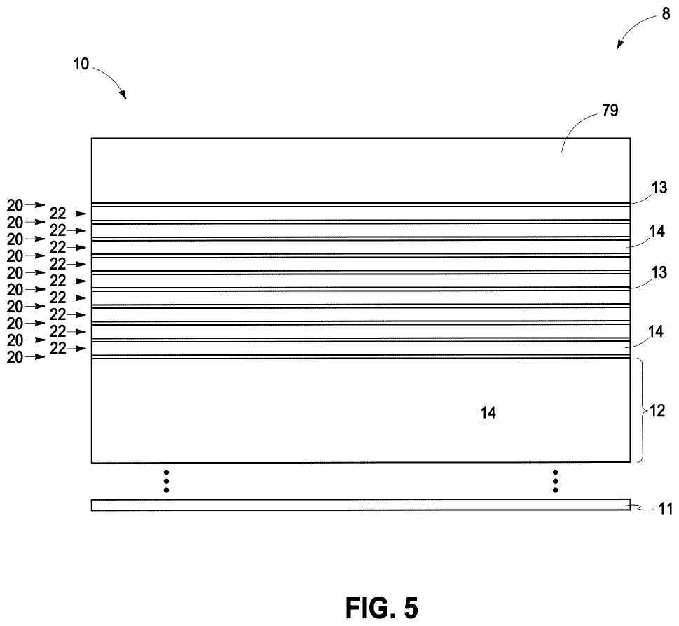

Referring to FIGS. 3-5, an example fragment of a substrate construction 8 comprising a memory-array region area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-5—depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array. Memory-array region 10 will ultimately comprise vertically-alternating insulative tiers and memory-cell tiers, for example that will be vertically-located as shown by arrows 20 and 22*, respectively, in FIG. 5 (an * being used as a suffix to be inclusive of all such same-numerically-designated structures or portions thereof that may or may not have other suffixes).

Semiconductor material 12 is above base substrate 11. In one embodiment, semiconductor material 12 comprises silicon material 14 (e.g., elemental monocrystalline or polycrystalline silicon and which may include one or more additional elements). If, by way of example, base substrate 11 is bulk monocrystalline silicon, silicon material 14 may be an upper or uppermost portion of such bulk monocrystalline silicon.

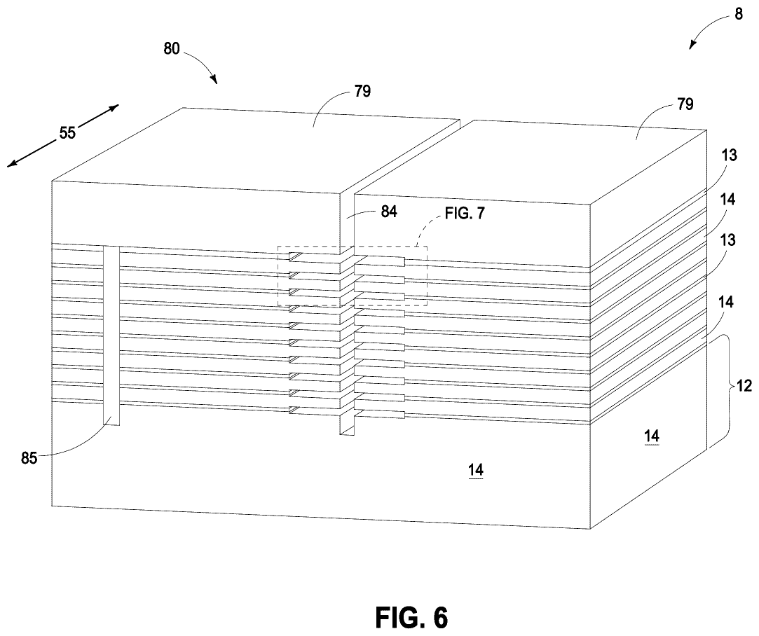

In one embodiment, vertically-alternating layers comprising silicon material 14 and silicon-germanium material 13 have been formed (e.g., epitaxially) directly above semiconductor material 12. Example silicon-germanium material 13 is Si₁₋ₓGeₓ, and which may include one or more additional elements. Materials 14 and 13 are ideally of etchably-different compositions relative one another. An example manner of epitaxially forming silicon material 14 includes using SiH₄, Si₂H₆, H₂SiCl₂, HCl, and Cl₂ as precursors at 300° C. to 1,500° C. and 100 mTorr to 100 Torr, and adding GeH₄ as an example germanium source when forming silicon-germanium material 13. An example isolation wall 85 extends vertically through materials 13 and 14, into semiconductor material 12, and is horizontally-elongated along a first direction 55. An insulating layer 79 (e.g., silicon dioxide) may be atop the uppermost layer of materials 13 and 14, as shown. Only a few layers of materials 13 and 14 are shown, with construction 8 in reality having many more such layers. Base substrate 11 is no longer shown in FIGS. 6+ for brevity.

The layers comprising materials 13 and 14 extend from memory-array region 10 into a connection region (e.g., 80 and/or 81). In this document, a “connection region” is a region in which electrical connection is made to a horizontally-extending conductive access line by a conductive-via construction, examples of both of which are described below. In the example embodiment, construction 8 includes two connection regions 80 and 81 which are on opposite first-direction sides of memory-array region 10. A horizontally-elongated trench 84 has been formed to extend through the layers comprising materials 13 and 14 in the connection region (e.g., in each of connection regions 80 and 81, horizontally-elongated along first direction 55, and extending into semiconductor material 12).

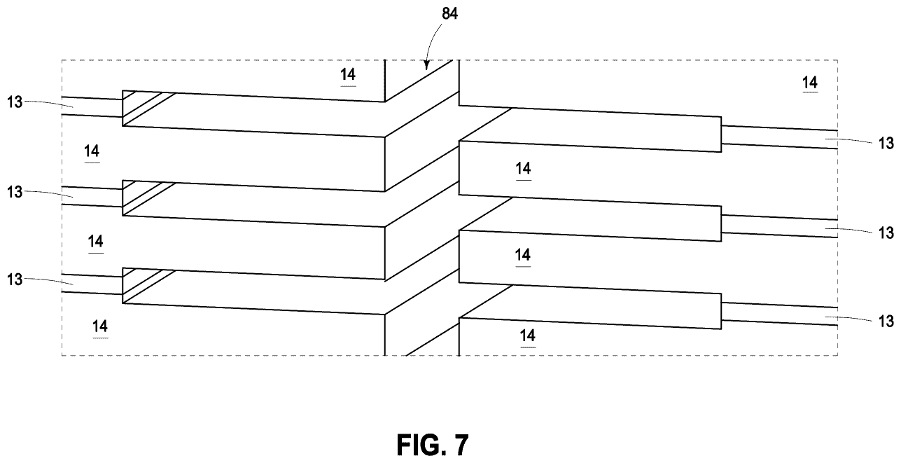

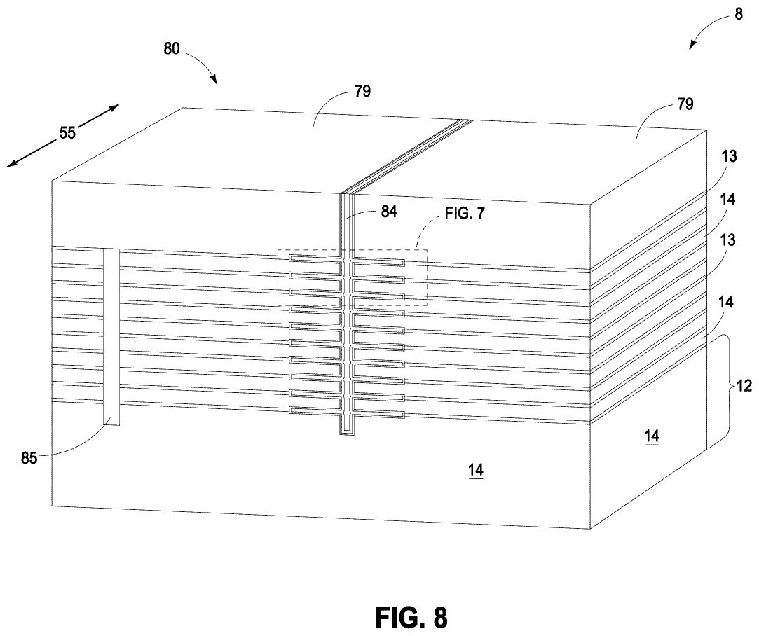

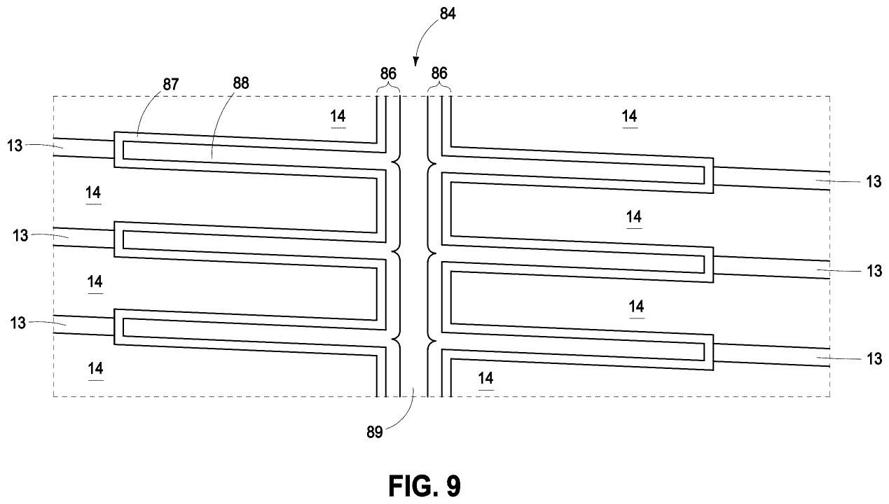

Through trench 84, silicon-germanium material 13 is replaced on opposing lateral sides of trench 84 with insulator material. As an example manner of doing so, FIGS. 6 and 7 show timed-etching of silicon-germanium material 13 through trench 84 selectively relative to silicon material 14, followed by etching silicon material 14 to vertically expand the void-spaces left thereby. FIGS. 8 and 9 show subsequent formation of insulator material 86 to replace silicon-germanium material 13 that was removed. In one embodiment, insulator material 86 comprises a first-in-sequence-formed silicon nitride-comprising layer 87 and a second-in-sequence-formed silicon dioxide layer 88. In one such latter embodiment, and as shown, silicon nitride-comprising layer 87 and silicon dioxide layer 88 do not completely fill horizontally-elongated trench 84 as initially-formed. Thereafter, remaining-volume of horizontally-elongated trench 84 is filled with a third-in-sequence-formed silicon dioxide layer 89 using a forming technique (e.g., chemical vapor deposition) that is different from a forming technique used to form second-in-sequence-formed silicon dioxide layer 88 (e.g., atomic layer deposition).

Referring to FIGS. 2 and 10-15, remaining silicon-germanium material 13 has been removed (at least in memory array area 10 and no longer there-shown; e.g., by etching) selectively relative to silicon material 14, and in one embodiment with such silicon material 14 during such removing and/or subsequently being at least partially thinned, for example in manners not material to the inventions disclosed herein (as shown; e.g., as shown in Micron Technology's U.S. Patent Application Publication Nos. 2022/0254784, 2022/0130834, U.S. Pat. No. 11,342,218, etc.). Vertically-alternating tiers 20 and 22* of insulative material 24 (e.g., silicon dioxide) and memory cells MC, respectively, have then been formed.

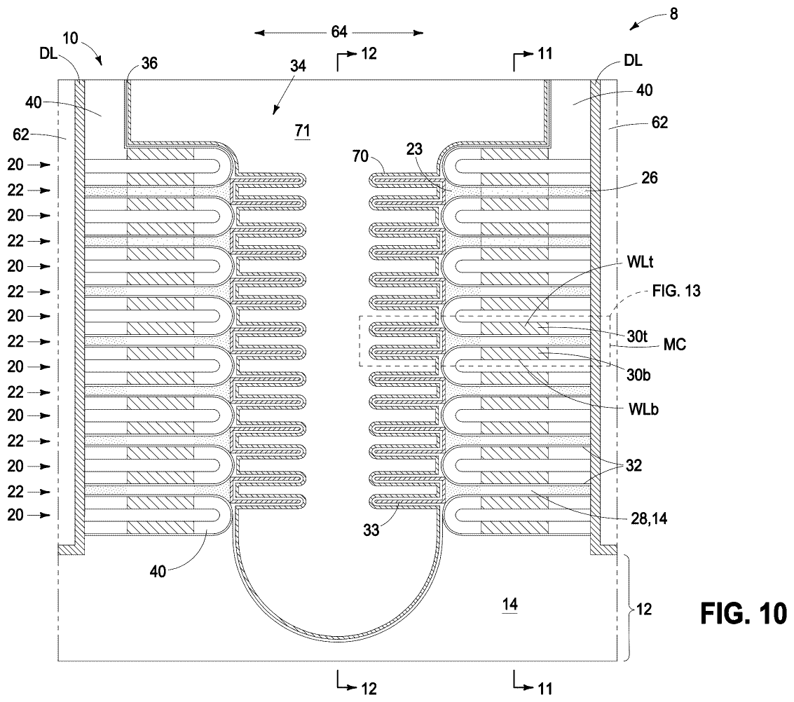

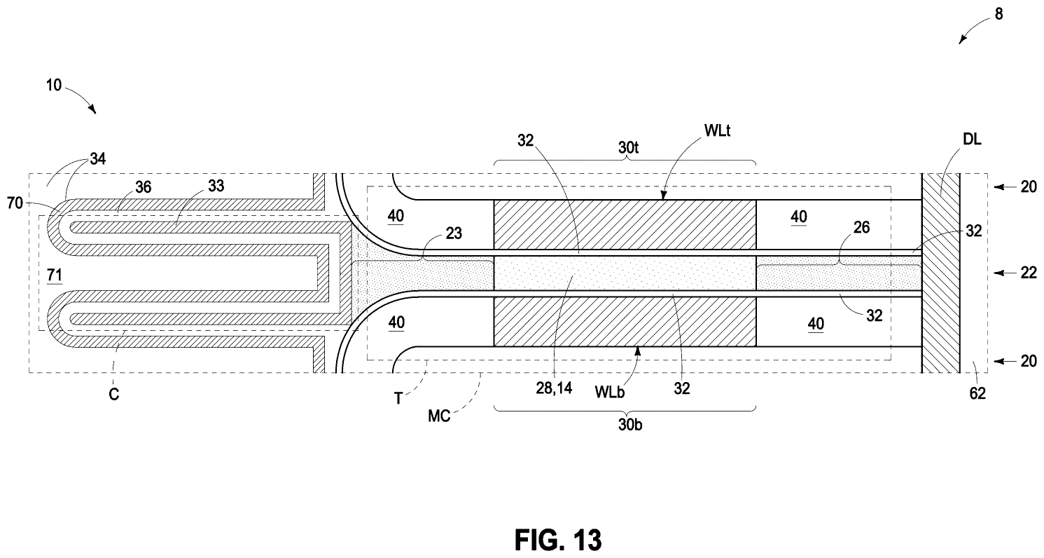

Memory cells MC individually comprise a horizontal transistor T that in one embodiment comprises a top gate 30t that is part of a top access line WLt, a bottom gate 30b that is part of a bottom access line WLb, and a channel or channel material 28 comprising silicon material 14 vertically there-between (e.g., gate-all-around the channel, with a gate insulator 32 [e.g., dielectric or ferroelectric] between at least channel material 28 and gates 30t, 30b; e.g., gates 30t, 30b comprising conductive metal material). Example transistor T comprises source/drain regions 23 and 26 (indicated with heavier stippling than channel material 28) having silicon material/channel material 14, 28 laterally there-between. Regions 23, 26, and 28 of different immediately-horizontally-adjacent memory cells MC into and out of the plane of the page upon which FIGS. 10 and 13 lie in a common memory-cell tier 22 may be isolated relative one another by insulative material (not shown). An example insulator 40 (e.g., silicon nitride) is laterally against lateral sides/edges of gates 30*. Source/drain regions 23 and 26 are individually shown as having a lateral edge that is laterally-coincident with a lateral edge of gate 30*, although there may be a dopant-concentration gradient between channel material 28 and a highest-dopant concentration within source/drain regions 23 and/or 26. Additionally and/or alternately, source/drain regions 23 and/or 26 may include an LDD region, a halo region, etc. (neither being shown).

Example memory cells MC individually comprise a capacitor C comprising a storage-node electrode 33, a common cell plate 34 (e.g., comprising conductive metal material 70 and conductively-doped polysilicon 71), and a capacitor insulator 36 there-between (e.g., dielectric or ferroelectric). Source/drain region 23 of transistor T is directly electrically coupled with and/or may be considered as a part of storage-node electrode 33. Source/drain region 26 of transistor T is directly electrically coupled with a digitline DL. Digitlines DL of different immediately-horizontally-adjacent memory cells MC into and out of the plane of the page upon which FIGS. 10 and 13 lie in a common memory-cell tier 22* may be isolated relative one another by insulative material (not shown). Example insulator material 62 (e.g., silicon dioxide and/or silicon nitride) is aside digitlines DL.

Top access line WLt, bottom access line WLb, and in one embodiment silicon material 14/channel material 28, extend horizontally along first direction 55 from memory-array region 10 into connection regions 80 and 81. As shown, channel material 14/28 in connection regions 80, 81 extends laterally-beyond a same one lateral side 42 of top and bottom access lines WLt and WLb in a second direction 64 that is orthogonal to first direction 55.

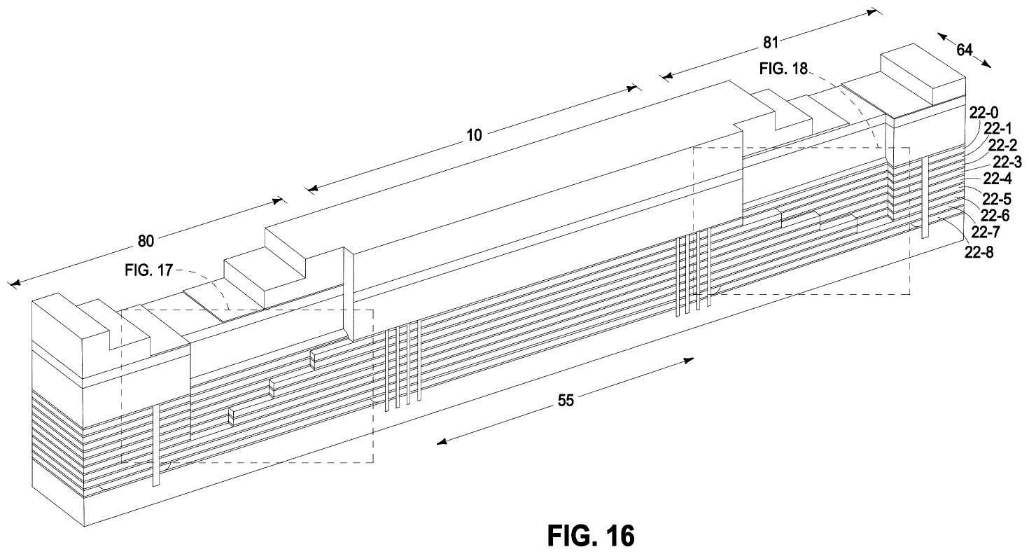

Referring to FIGS. 16-18, and in one embodiment, example memory-cell tiers 22 may be considered as comprising consecutively-numbered memory-cell tiers 22-0, 22-1, 22-2, 22-3, 22-4, 22-5, 22-6, 22-7, 22-8, etc. from top to bottom, including odd-numbered memory-cell tiers (e.g., 22-1, 22-3, 22-5, 22-7, etc.) and even-numbered memory-cell tiers (e.g., 22-0, 22-2, 22-4, 22-6, 22-8, etc.). Further and regardless, in one embodiment, FIGS. 16-18 show stairs 45 as having been formed in connection regions 80 and 81 (e.g., connection regions 80 and 81 individually comprising a stair-step region 80 or 81 in the depicted embodiment). Example stairs 45 comprise treads 47 comprising channel material 14/28 that extends laterally-beyond one lateral side 42. In one embodiment and as shown, the collective patterning to form stairs 45 has the top of each tread 47 as comprising channel material 14/28 of only the odd-numbered or only the even-numbered memory-cell tiers in each of stair-step regions 80 and 81 (e.g., even in 80, odd in 81). By way of example only, such may be formed by patterning a hardmask to cover the array region, yet with lower openings there-though to the top layer of channel material 14/28 in stair-step regions 80 and 81 where the stairs are to be collectively formed. One of those lower openings could then be filled with fill-material, with a mask-opening formed there-through to the other lower opening. Then, through the other lower opening, etching could be conducted through a layer of silicon material 14 and a layer of silicon-germanium material 13. The fill-material would then be removed, and a photoresist layer deposited and patterned with an upper opening there-through to each of the lower openings for forming the first/lowest stair in each stair-step region 80 and 81. Conventional etch/photoresist-trim/etch/photoresist-trim, etc., two layers of materials 13, 14 at a time, could then be conducted to form the illustrated construction.

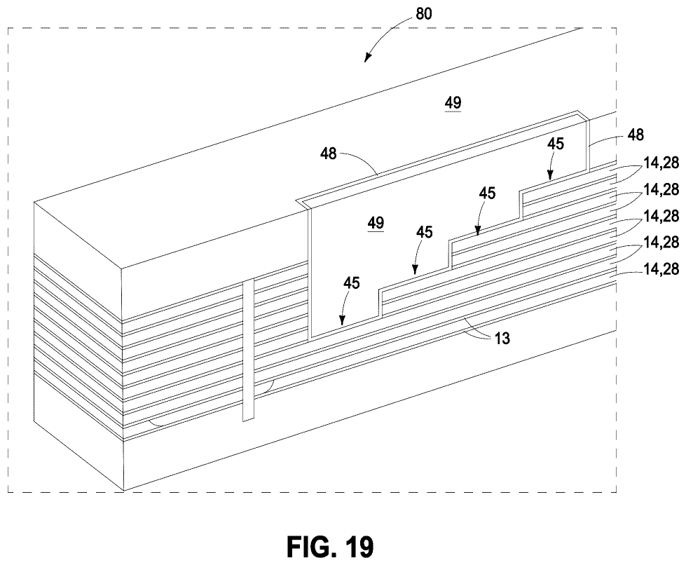

FIG. 19 shows filling of the cavities in which stairs 45 have been formed with an example silicon-nitride liner 48 and example silicon dioxide 49 thereover.

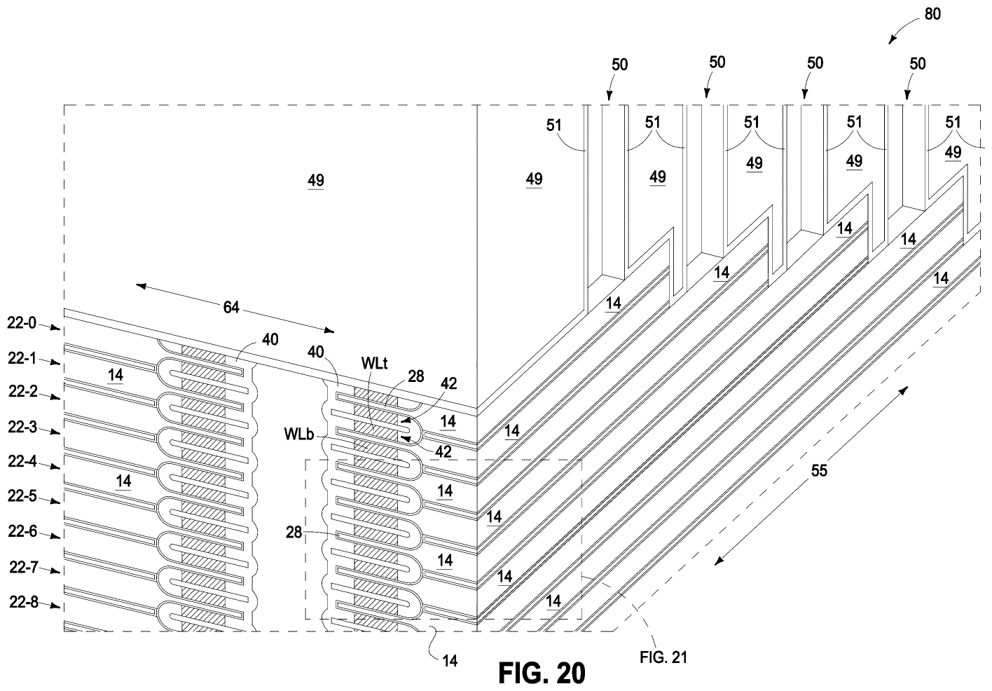

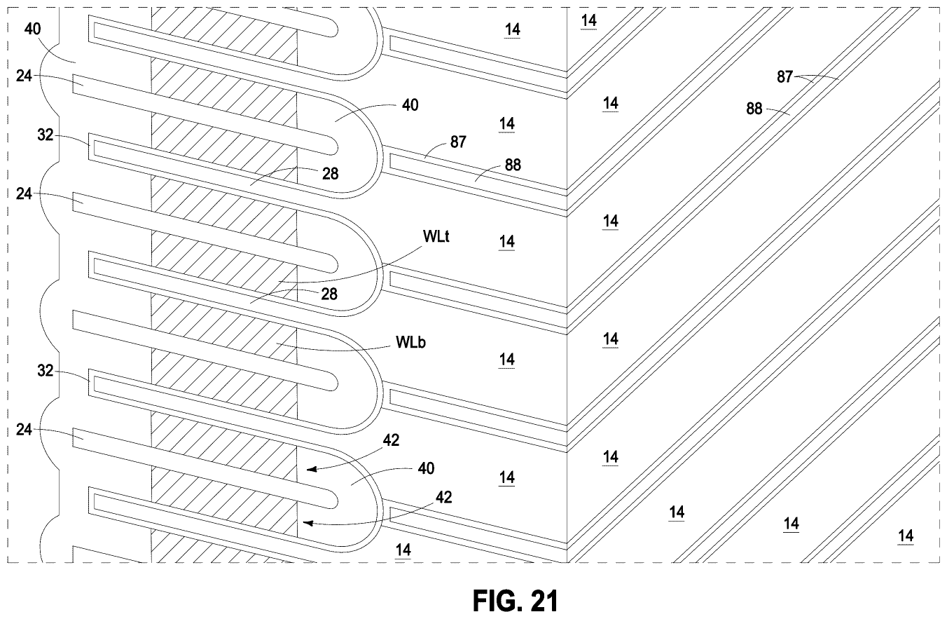

Referring to FIGS. 20 and 21, such are diagrammatic representations of a reverse side and section view of a portion of FIG. 19, looking right-to-left, of a portion of connection region 80. Therein, contact openings 50 have been formed downward to individually extend to channel material 14/28 that extends laterally-beyond one lateral side 42 of top and bottom access lines WLt and WLb in individual memory-cell tiers 22* (only shown in/for connection region 80 to even-numbered tiers 22-0, 22-2, 22-4, 22-6 for brevity. Analogous contact openings 50 would be formed in connection region 81 to odd-numbered tiers 22-1, 22-3, 22-5, 22-7). Contact openings 50 are individually laterally-spaced in second direction 64 from their respective top and bottom access lines WLt and WLb. In one embodiment and as shown, an insulating lining 51 (e.g., silicon nitride) has been formed in the contact openings 50 and then punch-etched to expose such channel material 14/28.

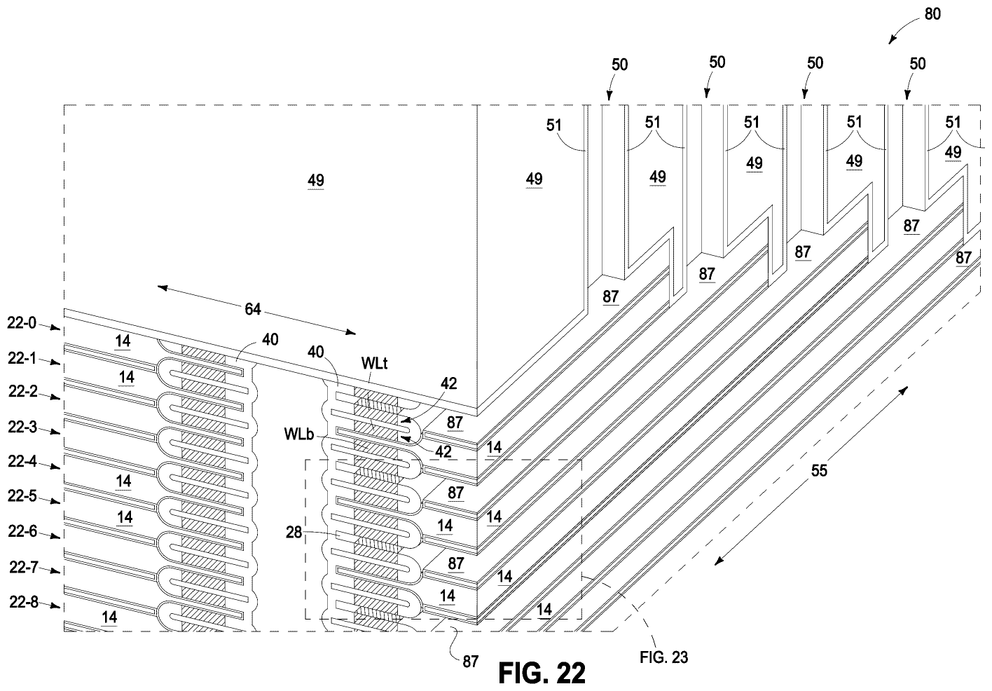

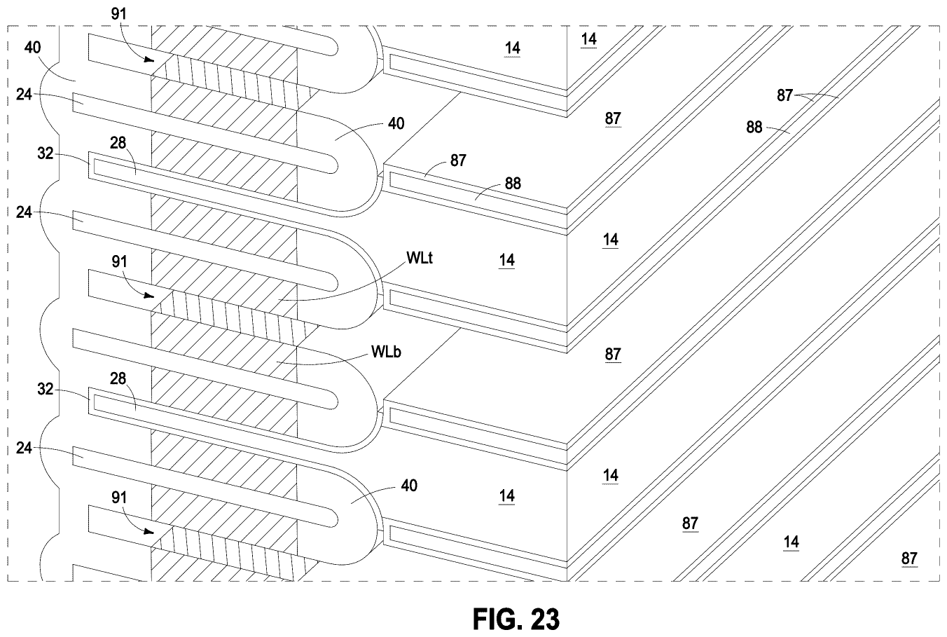

Referring to FIGS. 22 and 23, through contact openings 50, channel material 14/28 has been removed (e.g., at least some; e.g., by selective etching) from being vertically between the respective top and bottom access lines WLt and WLb in the connection region (e.g., 80 and 81) to create a void-space 91 vertically between the respective top and bottom access lines WLt and WLb in the connection region. In one embodiment and as shown, where gate insulator 32 is vertically between channel material 14/28 and each of top and bottom access lines WLt and WLb in the connection region, gate insulator 32 in the connection region has thereafter been removed as shown (e.g., by a selective etch) to expose the conductive material of access lines WLt and WLb to void-space 91. Channel material 14/28 would also likely be removed on the left-side of FIG. 22 in illustrated memory-cell tiers 22-0, 22-2, 22-4, and 22-6 (not shown) through corresponding contact openings 50 formed thereto (not visible) but is not shown for brevity. In connection region 81, channel material 14/28 would be removed through corresponding contact openings 50 (not shown) in memory-cell tiers 22-1, 22-3, 22-5, and 22-7 that are visible in FIGS. 22 and 23 and there (81) channel material 14/28 would be in tiers 22-0, 22-2, 22-4, and 22-6.

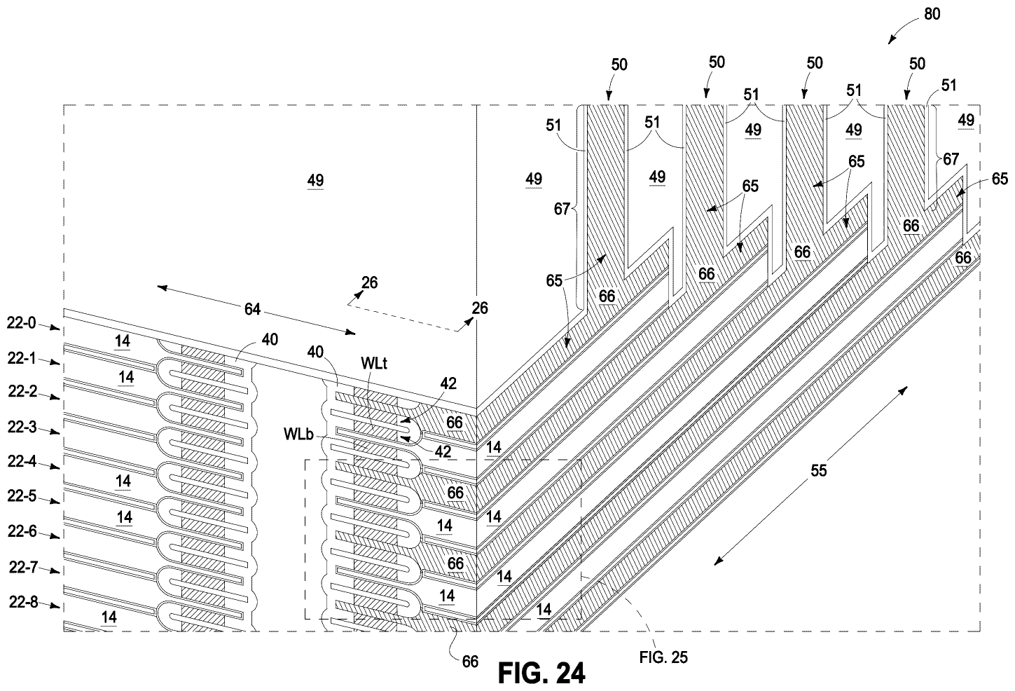

Referring to FIGS. 24-26, after removing channel material 14/28, a conductive-via construction 65 has been formed in individual of contact openings 50. Conductive-via construction 65 comprises conductive material 66 (e.g., conductive metal material) in void-space 91 that is directly against both of respective top and bottom access lines WLt and WLb. Conductive material 66 may be of the same or different composition as that of top and bottom access lines WLt and WLb (different being shown). Conductive-via constructions also comprise a vertically-elongated conductive portion 67 (e.g., comprising conductive material 66) that is laterally-spaced in second direction 64 from respective top and bottom access lines WLt and WLb and is directly electrically coupled to the conductive material 66 that is in void-space 91 (e.g., individual conductive-via constructions comprising a conductive part 68 that is vertically between and directly electrically coupled to top and bottom access lines WLt and WLb in connection region 80 and/or 81; e.g., gate insulator 32 when present having been removed previously so that conductive material 66 is directly against the respective top and bottom access lines WLt and WLb where gate insulator 32 was). Conductive-via construction 65 may comprise multiple different composition materials (not shown). For example, and by way of example only, vertically-elongated conductive portion 67 may comprise a conductive metal material liner and a different composition conductive metal core, with the liner only extending to between WLt and WLb (not shown).

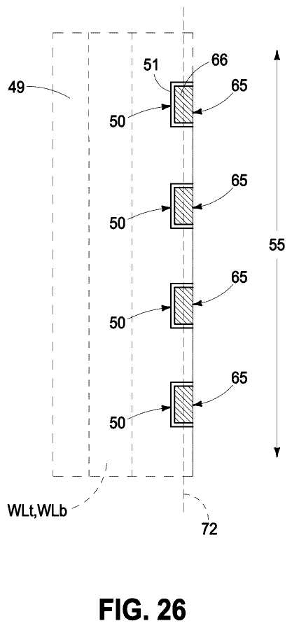

In one embodiment and as shown, multiple of contact openings 50 and multiple of vertically-elongated conductive portions 67 are laterally-spaced relative one another along a straight line 72 (FIG. 26) that is parallel first direction 55. In one embodiment, contact openings 50 and conductive-via constructions 65 in individual of two connection regions 80, 81 collectively extend to have respective bottoms that are in only one of (a) one of the odd-numbered memory-cell tiers, or (b) one of the even-numbered memory-cell tiers (as exemplified by the inherent nature of connection regions 80 and 81 in FIGS. 16-18 only having treads of only one of the odd-numbered memory-cell tiers [connection region 81] or only one of the even-numbered memory-cell tiers [connection region 80]).

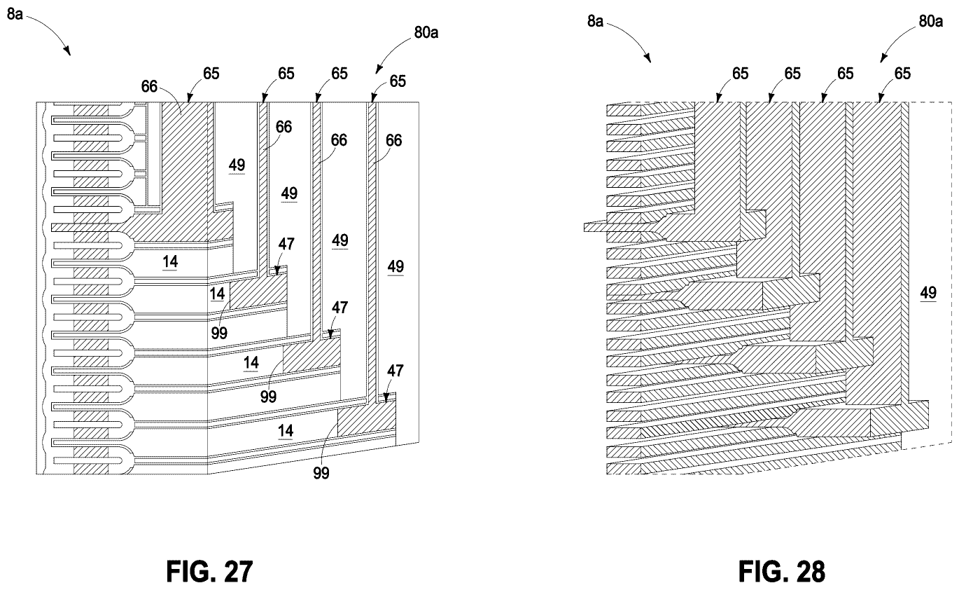

FIGS. 20-26, by way of example only and for ease of depiction, show all channel material 14/28 that was there-visible as having been removed and replaced by conductive material 66 of conductive-via constructions 65. However, such is not necessary and likely not all will be so removed, more likely resulting in a construction 8a in connection region 80a as exemplified in FIGS. 27 and 28. Like numerals from the above-described embodiments have been used where appropriate, with some construction differences being indicated with the suffix “a” or with different numerals. FIG. 28 is the same as FIG. 27 but for only showing conductive material for better clarity (e.g., 66, WLt, WLb). FIG. 27 also shows an example embodiment wherein channel material 28/14 is directly against a lateral side 99 of conductive material 66 of a conductive tread 47.

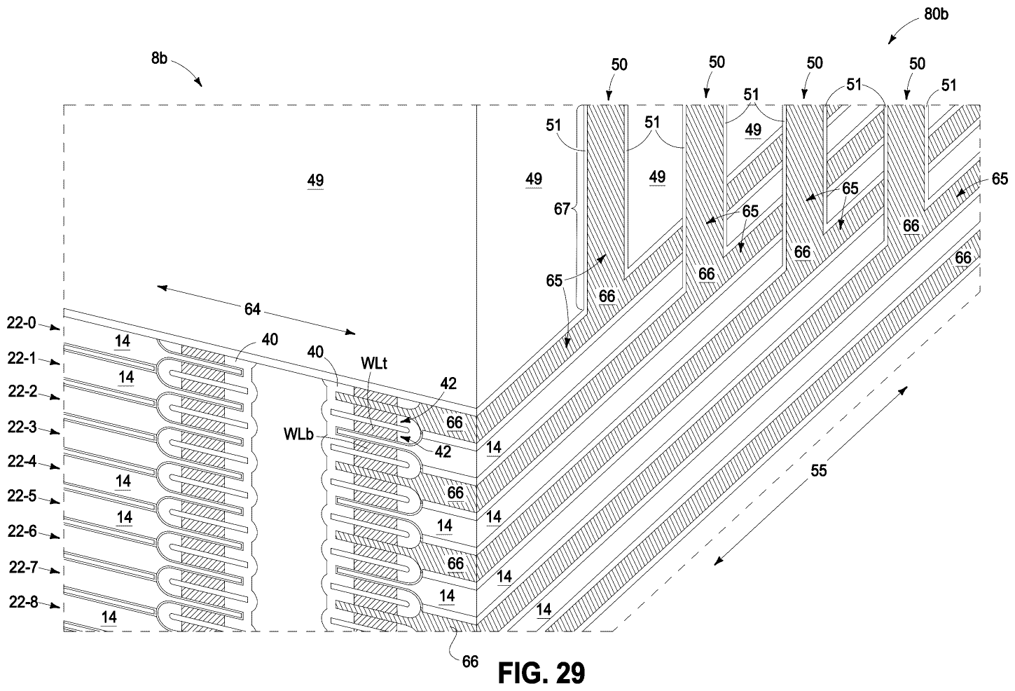

FIG. 29 shows an example alternate construction 8b (analogous to FIG. 24) where the connection region (e.g., 80b) does not have stairs and treads (e.g., “staircase-less”). Like numerals from the above-described embodiments have been used where appropriate, with some construction differences being indicated with the suffix “b” or with different numerals. The artisan in the depicted example is able to determine the number of alternating tiers and materials to be etched (e.g., using different etching chemistries for different materials) to be able to land individual contact openings 50 on a desired/selected memory-cell tier 22* in the absence of a stairs and only one or two insulative materials there-over. Again, for clarity in the disclosure of conductive material 66 extending to and physically contacting WLt and WLb, FIG. 29 shows conductive material completely filling tiers 22-0, 22-2, 22-4, and 22-6 in that portion of construction 8b that is visible. However, such removal and replacement of channel material 28/14 with conductive material 66 through contact openings 50 will typically and ideally only be more local (more proximate contact openings 50 as to also distal therefrom), for example as shown in FIGS. 27 and 28.

Any other attribute(s) or aspect(s) as shown and/or described herein with respect to other embodiments may be used in the embodiments shown and described with reference to the above embodiments.

In one embodiment, a method used in forming memory circuitry (e.g., 8, 8a, 8b) comprising memory cells (e.g., MC) comprises forming vertically-alternating insulative tiers (e.g., 20) and memory-cell tiers (e.g., 22*). The memory cells individually comprise a horizontal transistor (e.g., T) comprising a top gate (e.g., 30t) that is part of a top access line (e.g., WLt), a bottom gate (e.g., 30b) that is part of a bottom access line (e.g., WLb), and channel material (e.g., 28) vertically there-between. The top access line, the bottom access line, and the channel material extend horizontally along a first direction (e.g., 55) from a memory-array region (e.g., 10) in which the memory cells are received into a connection region (e.g., 80, 80b and/or 81). The channel material in the connection region extends laterally-beyond a same one lateral side (e.g., 42) of the top and bottom access lines in a second direction (e.g., 64) that is orthogonal to the first direction. In the connection region, contact openings (e.g., 50) are formed downward to individually extend to the channel material that extends laterally-beyond the one lateral side of the top and bottom access lines in individual of the memory-cell tiers. The contact openings are individually laterally-spaced in the second direction from their respective top and bottom access lines. Through the contact openings, the channel material is removed from being vertically between the respective top and bottom access lines to create a void-space (e.g., 91) vertically between the respective top and bottom access lines in the connection region. After the removing of the channel material, a conductive-via construction (e.g., 65) is formed in individual of the contact openings. The conductive-via construction comprises conductive material (e.g., 66) in the void-space that is directly against both of the respective top and bottom access lines. The conductive-via construction also comprises a vertically-elongated conductive portion (e.g., 67) that is laterally-spaced in the second direction from the respective top and bottom access lines and is directly electrically coupled to the conductive material that is in the void-space. Any other attribute(s) or aspect(s) as shown and/or described herein with respect to other embodiments may be used.

In one embodiment, a method used in forming memory circuitry (e.g., 8, 8a, 8b) comprising memory cells (e.g., MC) comprises forming vertically-alternating insulative tiers (e.g., 20) and memory-cell tiers (e.g., 22*). The memory cells individually comprise a horizontal transistor (e.g., T) comprising a gate (e.g., 30*; e.g., regardless of whether including top and bottom gates) and channel material (e.g., 28) operatively-proximate the gate. The gate comprises part of one of a plurality of horizontal conductive access lines (e.g., WL*; e.g., regardless of whether including top and bottom access lines) that individually directly electrically couple together multiple of the gates of different ones of the horizontal transistors that are in the same memory-cell tier. The access lines and channel material extend horizontally from the memory-array region into a connection region (e.g., 80, 80b and/or 81). Through a contact opening (e.g., 50) in the connection region, the channel material (at least some) in the connection region is replaced with conductive material (e.g., 66). The conductive material is directly against one of the access lines in the connection region and comprises part of a conductive-via construction (e.g., 65) in the connection region.

In one embodiment, the conductive-via construction comprises a conductive tread (e.g., 47) of a stair (e.g., 45) that is laterally adjacent the one access line. In one such embodiment, the conductive-via construction comprises a vertically-elongated conductive portion (e.g., 67) that is directly electrically coupled to the conductive tread. In one such latter embodiment, the vertically-elongated conductive portion is directly above the conductive tread.

Any other attribute(s) or aspect(s) as shown and/or described herein with respect to other embodiments may be used.

Alternate embodiment constructions may result from method embodiments described above, or otherwise. Regardless, embodiments of the invention encompass circuitry independent of method of manufacture. Nevertheless, such circuitry arrays may have any of the attributes as described herein in method embodiments. Likewise, the above-described method embodiments may incorporate, form, and/or have any of the attributes described with respect to device embodiments.

In one embodiment, memory circuitry (e.g., 8, 8a, 8b) comprises a memory-array region (e.g., 10) comprising vertically-alternating tiers (e.g., 20, 22*) of insulative material (e.g., 24) and memory cells (e.g., MC). The memory cells individually comprise a horizontal transistor (e.g., T) comprising a gate (e.g., 30*). The gate comprises part of one of a plurality of horizontal conductive access lines (e.g., WL*) that individually directly electrically couple together multiple of the gates of different ones of the horizontal transistors that are in the same memory-cell tier. The access lines extend horizontally along a first direction (e.g., 55) from the memory-array region into a connection region (e.g., 80, 80b and/or 81). The connection region comprises conductive-via constructions (e.g., 65) that individually directly electrically couple to individual of the access lines. Individual of the conductive-via constructions comprise a vertically-elongated conductive portion (e.g., 67) that is laterally-spaced from the access line to which the individual conductive-via construction is directly electrically coupled in a second direction (e.g., 64) that is orthogonal to the first direction.

In one embodiment, the individual access lines comprise a top access line (e.g., WLt) and a bottom access line (e.g., WLb). The gate comprises a top gate (e.g., 30t) that is part of the top access line and comprises a bottom gate (e.g., 30b) that is part of the bottom access line. The individual conductive-via constructions comprise a conductive part (e.g., 68) that is vertically between and directly electrically coupled to the top and bottom access lines in the connection region. In one embodiment, the vertically-elongated conductive portions of multiple of the conductive-via constructions are laterally-spaced relative one another along a straight line (e.g., 72) that is parallel the first direction.

Any other attribute(s) or aspect(s) as shown and/or described herein with respect to other embodiments may be used.

In one embodiment, memory circuitry (e.g., 8, 8a, 8b) comprises a memory-array region comprising vertically-alternating tiers (e.g., 20, 22*) of insulative material (e.g., 24) and memory cells (e.g., MC). The memory cells individually comprise a horizontal transistor (e.g., T) comprising a gate (e.g., 30*). The gate comprises part of one of a plurality of horizontal conductive access lines (e.g., WL*) that individually directly electrically couple together multiple of the gates of different ones of the horizontal transistors that are in the same memory-cell tier. The access lines extend horizontally from the memory-array region into a stair-step region (e.g., 80 and/or 81) comprising stairs (e.g., 45). Conductive-via constructions (e.g., 65) are in the stair-step region. The conductive-via constructions individually comprise a conductive tread (e.g., 47) of one of the stairs that directly electrically couples to one of the access lines in different ones of the memory-cell. The conductive-via constructions also individually comprise a vertically-elongated conductive portion (e.g., 67) that is directly electrically coupled to the conductive tread of the one stair and is laterally-spaced from the one access line.

In one embodiment, the vertically-elongated conductive portion is directly above the conductive tread. In one embodiment, the horizontal transistor comprises channel material that is operatively proximate the gate, with the channel material extending horizontally from the memory-array region into the stair-step region. In one such latter embodiment, the channel material is directly against a lateral side (e.g., 99) of conductive material (e.g., 66) of the conductive tread.

Any other attribute(s) or aspect(s) as shown and/or described herein with respect to other embodiments may be used.

Methods and/or structures as disclosed herein may enable easier locating of contact openings 50 as such are not required to be within the lateral confirms of the access lines as in prior methods and/or constructions. Further, in method, risk of tier collapse may be reduced when only etching one time through a single material 49 for contact openings 50 as opposed to etching multiple times through multiple different composition materials 13 and 14 in prior methods.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming memory circuitry comprising memory cells comprises forming vertically-alternating insulative tiers and memory-cell tiers. The memory cells individually comprise a horizontal transistor comprising a gate and channel material operatively-proximate the gate. The gate comprises part of one of a plurality of horizontal conductive access lines that individually directly electrically couple together multiple of the gates of different ones of the horizontal transistors that are in the same memory-cell tier. The access lines and channel material extend horizontally from the memory-array region into a connection region. Through a contact opening in the connection region. The channel material in the connection region is replaced with conductive material. The conductive material is directly against one of the access lines in the connection region and comprises part of a conductive-via construction in the connection region.

In some embodiments, a method used in forming memory circuitry comprising memory cells comprises forming vertically-alternating insulative tiers and memory-cell tiers. The memory cells individually comprise a horizontal transistor comprising a top gate that is part of a top access line, a bottom gate that is part of a bottom access line, and channel material vertically there-between. The top access line, the bottom access line, and the channel material extend horizontally along a first direction from a memory-array region in which the memory cells are received into a connection region. The channel material in the connection region extends laterally-beyond a same one lateral side of the top and bottom access lines in a second direction that is orthogonal to the first direction. In the connection region, contact openings are formed downward to individually extend to the channel material that extends laterally-beyond the one lateral side of the top and bottom access lines in individual of the memory-cell tiers. The contact openings individually are laterally-spaced in the second direction from their respective top and bottom access lines. Through the contact openings, the channel material is removed from being vertically between the respective top and bottom access lines to create a void-space vertically between the respective top and bottom access lines in the connection region. After the removing, a conductive-via construction is formed in individual of the contact openings. The conductive-via construction comprises conductive material in the void-space that is directly against both of the respective top and bottom access lines. The conductive-via construction also comprises a vertically-elongated conductive portion that is laterally-spaced in the second direction from the respective top and bottom access lines and is directly electrically coupled to the conductive material that is in the void-space.

In some embodiments, a method used in forming memory circuitry comprises forming vertically-alternating layers comprising silicon material and silicon-germanium material directly above a substrate. The layers extend from a memory-array region into a connection region. The memory-array region ultimately comprises vertically-alternating insulative tiers and memory-cell tiers. The memory-cell tiers ultimately comprise memory cells in the memory-array region that individually comprise a horizontal transistor comprising a top gate that is part of a top access line, a bottom gate that is part of a bottom access line, and a channel comprising the silicon material vertically there-between. The top access line, the bottom access line, and the silicon material of the channel ultimately extend horizontally along a first direction from the memory-array region into the connection region. The silicon material in the connection region extends laterally-beyond a same one lateral side of the top and bottom access lines in a second direction that is orthogonal to the first direction. A horizontally-elongated trench is formed through the layers in the connection region. Through the trench, the silicon-germanium material on opposing lateral sides of the trench is replaced with insulator material. In the connection region, contact openings are formed downward to individually extend to the silicon material that extends laterally-beyond the one lateral side of the top and bottom access lines in individual of the memory-cell tiers. The contact openings individually are laterally-spaced in the second direction from their respective top and bottom access lines. Through the contact openings, the silicon material is removed from being vertically between the respective top and bottom access lines in the connection region to create a void-space vertically between the respective top and bottom access lines in the connection region. After the removing, a conductive-via construction is formed in individual of the contact openings. The conductive-via construction comprises conductive material in the void-space that is directly against both of the respective top and bottom access lines. The conductive-via construction also comprises a vertically-elongated conductive portion that is laterally-spaced in the second direction from the respective top and bottom access lines and is directly electrically coupled to the conductive material that is in the void-space.

In some embodiments, memory circuitry comprises a memory-array region comprising vertically-alternating tiers of insulative material and memory cells. The memory cells individually comprise a horizontal transistor comprising a gate. The gate comprises part of one of a plurality of horizontal conductive access lines that individually directly electrically couple together multiple of the gates of different ones of the horizontal transistors that are in the same memory-cell tier. The access lines extend horizontally along a first direction from the memory-array region into a connection region. The connection region comprises conductive-via constructions that individually directly electrically couple to individual of the access lines. Individual of the conductive-via constructions comprise a vertically-elongated conductive portion that is laterally-spaced from the access line to which the individual conductive-via construction is directly electrically coupled in a second direction that is orthogonal to the first direction.

In some embodiments, memory circuitry comprises a memory-array region comprising vertically-alternating tiers of insulative material and memory cells. The memory cells individually comprise a horizontal transistor comprising a gate. The gate comprises part of one of a plurality of horizontal conductive access lines that individually directly electrically couple together multiple of the gates of different ones of the horizontal transistors that are in the same memory-cell tier. The access lines extend horizontally from the memory-array region into a stair-step region comprising stairs. Conductive-via constructions are in the stair-step region. The conductive-via constructions individually comprise a conductive tread of one of the stairs that directly electrically couples to one of the access lines in different ones of the memory-cell tiers. The conductive-via constructions also individually comprise a vertically-elongated conductive portion is directly electrically coupled to the conductive tread of the one stair and is laterally-spaced from the one access line.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry comprising memory cells, comprising:
forming vertically-alternating insulative tiers and memory-cell tiers, the memory cells individually comprising horizontal transistor comprising a gate and channel material operatively-proximate the gate, the gate comprising part of one of a plurality of horizontal conductive access lines that individually directly electrically couple together multiple of the gates of different ones of the horizontal transistors that are in the same memory-cell tier, the access lines and channel material extending horizontally from the memory-array region into a connection region; and
through a contact opening in the connection region, replacing the channel material in the connection region with conductive material, the conductive material being directly against one of the access lines in the connection region and comprising part of a conductive-via construction in the connection region.

2. The method of claim 1 wherein the conductive-via construction comprises a vertically-elongated conductive portion that is laterally-spaced from the one access line.

3. The method of claim 1 comprising:
a gate insulator vertically between the channel material and the access line in the connection region; and
removing the gate insulator in the connection region before forming the conductive material so that the conductive material is directly against the one access line through where the gate insulator was.

4. The method of claim 1 wherein the conductive-via construction comprises a conductive tread of a stair that is laterally adjacent the one access line.

5. The method of claim 4 wherein the conductive-via construction comprises a vertically-elongated conductive portion that is directly electrically coupled to the conductive tread.

6. The method of claim 5 wherein the vertically-elongated conductive portion is directly above the conductive tread.

7. The method of claim 1 comprising forming an insulating lining in the contact openings prior to the replacing.

8. The method of claim 1 wherein the memory cells individually comprise a capacitor and the memory circuitry comprises DRAM.

9. A method used in forming memory circuitry comprising memory cells, comprising:
forming vertically-alternating insulative tiers and memory-cell tiers; the memory cells individually comprising a horizontal transistor comprising a top gate that is part of a top access line, a bottom gate that is part of a bottom access line, and channel material vertically there-between; the top access line, the bottom access line, and the channel material extending horizontally along a first direction from a memory-array region in which the memory cells are received into a connection region, the channel material in the connection region extending laterally-beyond a same one lateral side of the top and bottom access lines in a second direction that is orthogonal to the first direction;
in the connection region, forming contact openings downward to individually extend to the channel material that extends laterally-beyond the one lateral side of the top and bottom access lines in individual of the memory-cell tiers; the contact openings individually being laterally-spaced in the second direction from their respective top and bottom access lines;
through the contact openings, removing the channel material from being vertically between the respective top and bottom access lines to create a void-space vertically between the respective top and bottom access lines in the connection region; and
after the removing, forming a conductive-via construction in individual of the contact openings; the conductive-via construction comprising:
conductive material in the void-space that is directly against both of the respective top and bottom access lines; and
a vertically-elongated conductive portion that is laterally-spaced in the second direction from the respective top and bottom access lines and is directly electrically coupled to the conductive material that is in the void-space.

10. The method of claim 9 wherein multiple of the contact openings and multiple of the vertically-elongated conductive portions are laterally-spaced relative one another along a straight line that is parallel the first direction.

11. The method of claim 9 wherein the conductive-via construction comprises a conductive part that is vertically between and directly electrically coupled to the respective top and bottom access lines.

12. The method of claim 9 comprising:
a gate insulator vertically between the channel material and each of the top and bottom access lines in the connection region; and
removing the gate insulator in the connection region before forming the conductive material so that the conductive material is directly against the respective top and bottom access lines where the gate insulator was.

13. The method of claim 9 wherein the conductive-via construction comprises a conductive tread of a stair that is laterally adjacent the top and bottom access lines.

14. The method of claim 9 wherein,
the connection region is one of two connection regions that are on opposite first-direction sides of the memory-array region;
the top and bottom access lines in the individual memory-cell tiers extend into each of the two connection regions;
the memory-cell tiers comprise consecutively-numbered memory-cell tiers from top to bottom, including odd-numbered memory-cell tiers and even-numbered memory-cell tiers; and
the contact openings and the conductive-via constructions in individual of the two connection regions collectively extending to have respective bottoms that are in only one of:
(a) one of the odd-numbered memory-cell tiers; or
(b) one of the even-numbered memory-cell tiers.

15. The method of claim 9 comprising forming an insulating lining in the contact openings prior to the removing.

16. A method used in forming memory circuitry, comprising:
forming vertically-alternating layers comprising silicon material and silicon-germanium material directly above a substrate, the layers extending from a memory-array region into a connection region, the memory-array region ultimately comprising vertically-alternating insulative tiers and memory-cell tiers; the memory-cell tiers ultimately comprising memory cells in the memory-array region that individually comprise a horizontal transistor comprising a top gate that is part of a top access line, a bottom gate that is part of a bottom access line, and a channel comprising the silicon material vertically there-between; the top access line, the bottom access line, and the silicon material of the channel ultimately extending horizontally along a first direction from the memory-array region into the connection region, the silicon material in the connection region extending laterally-beyond a same one lateral side of the top and bottom access lines in a second direction that is orthogonal to the first direction;
forming a horizontally-elongated trench through the layers in the connection region;
through the trench, replacing the silicon-germanium material on opposing lateral sides of the trench with insulator material;
in the connection region, forming contact openings downward to individually extend to the silicon material that extends laterally-beyond the one lateral side of the top and bottom access lines in individual of the memory-cell tiers; the contact openings individually being laterally-spaced in the second direction from their respective top and bottom access lines;
through the contact openings, removing the silicon material from being vertically between the respective top and bottom access lines in the connection region to create a void-space vertically between the respective top and bottom access lines in the connection region; and
after the removing, forming a conductive-via construction in individual of the contact openings; the conductive-via construction comprising:
conductive material in the void-space that is directly against both of the respective top and bottom access lines; and
a vertically-elongated conductive portion that is laterally-spaced in the second direction from the respective top and bottom access lines and is directly electrically coupled to the conductive material that is in the void-space.

17. The method of claim 16 comprising forming an insulating lining in the contact openings prior to the removing.

18. The method of claim 16 wherein the insulator material comprises a first-in-sequence-formed silicon nitride-comprising layer and a second-in-sequence-formed silicon dioxide layer.

19. Memory circuitry comprising:
a memory-array region comprising vertically-alternating tiers of insulative material and memory cells, the memory cells individually comprising a horizontal transistor comprising a gate, the gate comprising part of one of a plurality of horizontal conductive access lines that individually directly electrically couple together multiple of the gates of different ones of the horizontal transistors that are in the same memory-cell tier, the access lines extending horizontally along a first direction from the memory-array region into a connection region; and
the connection region comprising conductive-via constructions that individually directly electrically couple to individual of the access lines, individual of the conductive-via constructions comprising a vertically-elongated conductive portion that is laterally-spaced from the access line to which the individual conductive-via construction is directly electrically coupled in a second direction that is orthogonal to the first direction.

20. Memory circuitry comprising:
a memory-array region comprising vertically-alternating tiers of insulative material and memory cells, the memory cells individually comprising a horizontal transistor comprising a gate, the gate comprising part of one of a plurality of horizontal conductive access lines that individually directly electrically couple together multiple of the gates of different ones of the horizontal transistors that are in the same memory-cell tier, the access lines extending horizontally from the memory-array region into a stair-step region comprising stairs; and
conductive-via constructions in the stair-step region, the conductive-via constructions individually comprising:
a conductive tread of one of the stairs that directly electrically couples to one of the access lines in different ones of the memory-cell tiers; and
a vertically-elongated conductive portion that is directly electrically coupled to the conductive tread of the one stair and is laterally-spaced from the one access line.
